(19) United States
(12) Patent Application Publication
(10) Pub. No.: US 2008/0157380 A1
(43) Pub. Date: Jul. 3, 2008

(54) Method for forming metal interconnection of semiconductor device

(75) Inventor: Ji Ho Hong, Hwaseong-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/986,588

(22) Filed: Nov. 23, 2007

(30) Foreign Application Priority Data
Dec. 27, 2006 (KR) 10-2006-0135767

(51) Int. Cl. H01L 21/4763; H01L 23/528

(52) U.S. Cl. 257/751; 438/620; 257/E23.142; 257/E21.495

(57) ABSTRACT

Disclosed is a method for forming a metal interconnection in a semiconductor device. In a damascene process, a capping barrier metal layer is formed generally only on a lower metal interconnection in order to prevent the diffusion of atoms from the lower metal interconnection into an upper dielectric layer. The capping barrier metal layer prevents the increase of an effective dielectric constant of a lower inter-metal dielectric layer that surrounds the lower metal interconnection, and may reduce the resistance of the metal interconnection, thereby improving the reliability, speed and/or other characteristics of the semiconductor device.

The present application claims priority under 35 U.S.C. 119 and 35 U.S.C. 365 to Korean Patent Application No. 10-2006-0135767 (filed on Dec. 27, 2006), which is hereby incorporated by reference in its entirety.

### BACKGROUND

The present disclosure relates to a method for forming a metal interconnection of a semiconductor device.

In general, a metal interconnection of a semiconductor device connects circuits formed in a semiconductor substrate to each other through electrical connection(s) and pad connection(s) between semiconductor devices by using a metal thin film including aluminum, aluminum alloys, and copper.

In order to connect a pad with an electrode insulated from the pad by an insulating layer, such as an oxide layer, a contact hole is primarily formed by selectively etching the insulating layer, and then a metal plug for filling the contact hole is formed using barrier metal or tungsten. Then, after forming a subsequent metal thin film on the resultant structure (including in electrical contact with the plug), the metal thin film is patterned, thereby forming the metal interconnection for connecting the pad with the electrode.

In order to pattern the metal interconnection, a photolithography process is mainly used. However, the critical dimension of the metal interconnection has gradually decreased with successive generations of technology, so it has generally become more difficult to form the micro-pattern of the metal interconnection through the photolithography process with time. For this reason, a damascene process has been proposed to easily form the metal interconnection having the micro-pattern.

A metal interconnection formed through the damascene process generally has a multi-layer structure. In the case of the multi-layer metal interconnection including copper, to form the next level of metallization, a barrier layer including SiN and/or SiCN is formed on the entire surface of a lower copper metal interconnection and a lower inter-metal dielectric (IMD) layer in order to prevent the diffusion of a lower copper metal interconnection into an upper IMD layer that surrounds the upper copper metal interconnection. The SiN and/or SiCN layer may also act as an etch stop layer during formation of vias or contact holes in the upper IMD layer.

When the conventional barrier layer is formed on the entire surface of the lower copper metal interconnection and the lower IMD layer, an effective dielectric constant (k) of the lower IMD layer increases, thereby causing an increased RC delay. Thus, the reliability of the semiconductor device may be degraded.

### SUMMARY

Accordingly, the present disclosure provides a method for forming a metal interconnection of a semiconductor device capable of improving the speed and/or reliability of the semiconductor device by preventing the increase of an effective dielectric constant of an inter-metal dielectric layer caused by a barrier layer of the semiconductor device.

According to an aspect of the present disclosure, there is provided a method for forming a metal interconnection in a semiconductor device, which includes forming a via hole in a first dielectric layer on a semiconductor substrate, forming a first barrier layer on an inner wall of the via hole and a first metal interconnection on the first barrier; forming an additional insulating layer on the semiconductor substrate; forming a trench in the additional insulating layer, the trench having a second barrier layer on an inner wall thereof and a second metal interconnection on the second barrier layer; forming a second dielectric layer; forming a via hole and a trench in the second dielectric layer; forming a third barrier layer on inner walls of the via hole and the trench, and forming an upper metal interconnection on the third barrier; and forming an upper capping barrier metal layer on the upper metal interconnection.

According to another aspect of the present disclosure, there is provided a method for forming a metal interconnection in a semiconductor device, which includes forming a via hole in an insulating layer on a semiconductor substrate; forming a trench in the insulating layer overlapping the via hole; depositing a barrier metal layer and a metal interconnection layer; polishing the barrier metal layer and the metal interconnection layer until the insulating layer is exposed; and forming a capping barrier metal layer on the metal interconnection layer.

According to still another aspect of the present disclosure, there is provided a semiconductor device comprising: a semiconductor substrate having an isolation layer, a high-density junction area, a gate insulating layer and a gate electrode; a first insulating layer on the semiconductor substrate; a via hole in the first insulating layer, the via hole having a first barrier layer on an inner wall thereof and a first metal interconnection on the first barrier layer; a trench overlapping the via hole, the trench having a second barrier layer on an inner wall thereof and a second metal interconnection on the second barrier layer; a lower capping barrier metal layer covering the second metal interconnection in the trench; a second insulating layer on the first insulating layer; a via hole and a trench in the second insulating layer; a third barrier layer on inner walls of the via hole and the trench; an upper metal interconnection in the via hole and the trench; and an upper capping barrier metal layer on the upper metal interconnection.

### BRIEF DESCRIPTION OF THE DRAWINGS

FIG. 1 is a cross-sectional view of a semiconductor device implemented according to an embodiment;

FIGS. 2a to 2d are cross-sectional views illustrating an exemplary method for forming a lower metal interconnection according to an embodiment;

FIGS. 3a to 3c are cross-sectional views illustrating a method for forming an upper metal interconnection in the present method according to an embodiment;

FIGS. 4a to 4d are cross-sectional views sequentially illustrating an exemplary method for forming an capping barrier metal layer according to the present disclosure; and

FIGS. 5a to 5c are cross-sectional views sequentially illustrating another exemplary method for forming the capping barrier metal layer according to the present disclosure.

### DETAILED DESCRIPTION OF THE EMBODIMENTS

Hereinafter, a metal interconnection of a semiconductor device and a method for forming the same according to exemplary embodiments will be described in detail with respect to the accompanying drawings.

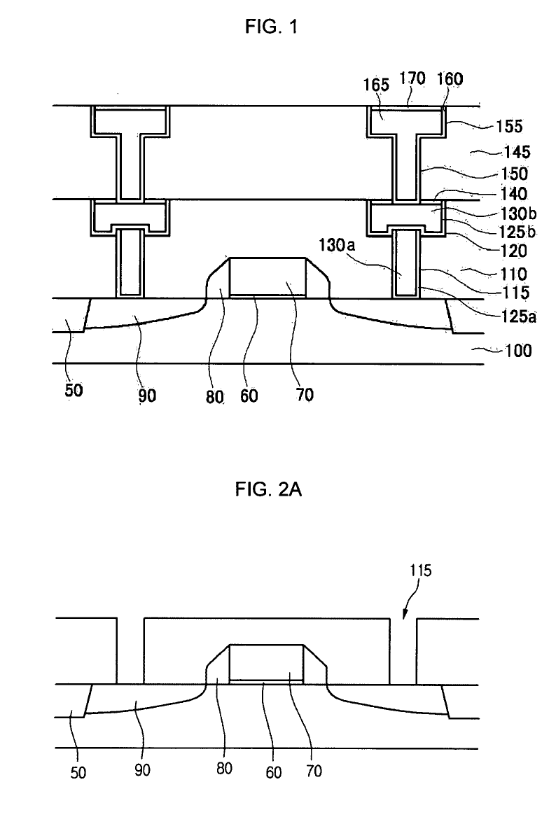

FIG. 1 is a cross-sectional view of a semiconductor device implemented according to an embodiment of the invention. First, the structure of the semiconductor device implemented according to the embodiment will be described in detail with reference to FIG. 1.

As illustrated in FIG. 1, a gate insulating layer 60 and a gate electrode 70 are sequentially formed on the semiconductor substrate 100 having an isolation layer 50 and a high-density (source/drain) junction area 90, and spacers 80 are formed at sides of the gate insulating layer 60 and the gate electrode 70, respectively.

A lower pre-metal dielectric (PMD) layer 110 having a lower via hole 115 and a lower trench 120 is formed on the semiconductor substrate 100, the gate electrode 70 and the spacers 80. First and second barrier layers 125a and 125b are respectively formed on inner walls of the lower via hole 115 and the lower trench 120.

Lower metal interconnections 130a and 130b are respectively formed on the first and second barrier layers 125a and 125b. Here, the lower metal interconnections 130a and 130b may include tungsten and copper, respectively. Thus, the first and second barrier layers 125a and 125b may include tungsten and copper diffusion barriers, respectively (e.g., titanium and/or titanium nitride, tantalum and/or tantalum nitride, hafnium and/or hafnium nitride, ruthenium, etc.). A lower capping barrier metal layer 140 is formed on the lower metal interconnection 130b.

An upper (or first) inter-metal dielectric (IMD) layer 145 having an upper via hole 150 and an upper trench 155 is formed on the lower PMD layer 110 and the lower capping barrier metal layer 140. A third barrier layer 160 is formed on inner walls of the upper via hole 150 and the upper trench 155. An upper metal interconnection 165 is formed on the third barrier layer 160. An upper capping barrier metal layer 170 having the same height as the IMD layer 145 (i.e., having coplanar uppermost surfaces) is formed on the upper metal interconnection 165.

Here, the lower and upper capping barrier metal layers 140 and 170 include a conductive metal such as Ti, TiSiN, TiN, Ta, TaN, WSiN, WN, MoN, HfN, TiW alloy or Ru. The first and second barrier layers 125a and 125b prevent atoms or ions from the lower metal interconnection 130 from being diffused into the lower PMD layer 110. Further, the third barrier layer 125 prevents atoms or ions from the upper metal interconnection 165 from being diffused into the IMD layer 145, and the lower capping barrier metal layer 140 prevents atoms or ions from the lower metal interconnection 130 from being diffused into the IMD layer 145.

The lower PMD layer 110 and the IMD layer 145 may include phosphorous silicate glass (PSG), boron phosphorous silicate glass (BPSG), fluorine doped silicate glass (FSG), a plasma silane (p-Si)-based glass, a TEOS-based glass and undoped silicate glass (USG), particularly in wafer fabrication processes or technologies having a minimum critical dimension of 0.13 μm or larger. In wafer fabrication processes having a minimum critical dimension of 0.11 μm or smaller, the lower PMD layer 110 and the IMD layer 145 may include the above glasses and low k dielectrics such a SiOC and/or SiOCH (available under the trade names BLACK DIAMOND [Applied Materials, Inc., Santa Clara, Calif.], and CORAL [Novellus, Inc., San Jose, Calif.]). In either case, the dielectric materials generally have a low effective dielectric constant, suitable for a particular wafer fabrication process or technology and particular set of target parameter values (e.g., a specification) for a given product.

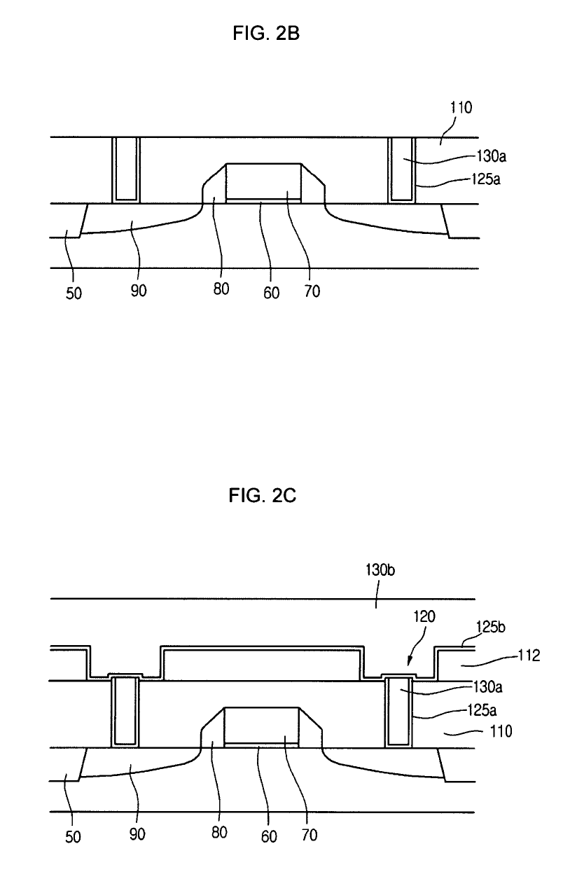

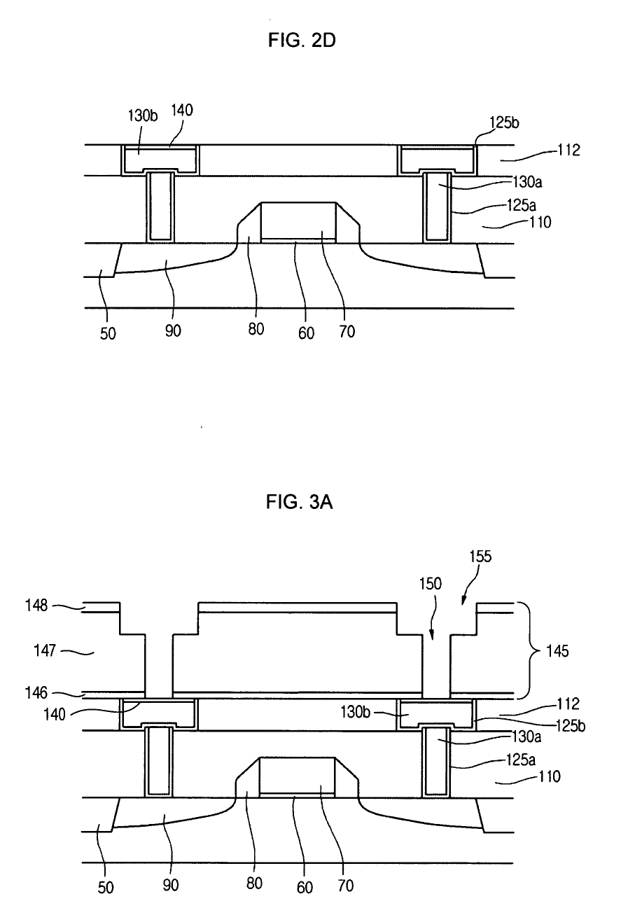

FIGS. 2a to 2d are cross-sectional views illustrating a method for forming a lower metal interconnection according to embodiments of the invention.

As illustrated in FIG. 2a, a gate insulating layer 60 and a gate electrode 70 are sequentially formed on the semiconductor substrate 100 formed with an isolation layer 50 and a high-density junction area 90, and spacers 80 are formed at sides of the gate insulating layer 60 and the gate electrode 70, respectively.

After that, a lower PMD layer 110 is formed (generally by blanket deposition) on the semiconductor substrate 100, the gate electrode 70 and the spacers 80, and a photoresist pattern (not shown) is formed on the lower PMD layer 110. The lower PMD layer 110 is etched using the photoresist pattern as a mask, thereby forming a lower via hole 115 exposing the semiconductor substrate 100.

As illustrated in FIG. 2b, a first barrier layer 125 is formed on an inner wall of the lower via hole 115, and a lower metal interconnection 130a is formed on the first barrier layer 125a. The first barrier layer 125a may be formed may be formed by a chemical vapor deposition (CVD) process (particularly a metal nitride layer), a physical vapor deposition (PVD) process such as sputtering (particularly an elemental metal layer or alloy layer, although metal nitride layers can also be formed by sputtering the elemental metal in an ammonia- and/or nitrogen-containing atmosphere or plasma), or an atomic layer deposition (ALD) process.

As illustrated in FIG. 2c, an additional PMD layer 112 may be deposited and patterned, thereby forming a lower trench 120. After that, a second barrier layer 125b is formed in the lower trench 120. A lower metal interconnection is formed on the second barrier layer 125b.

The second barrier layer 125b may be formed by a chemical vapor deposition (CVD) process, a physical vapor deposition (PVD) process, or an atomic layer deposition (ALD) process, as for the first barrier layer 125a.

As illustrated in FIG. 2d, a chemical mechanical polishing (CMP) process is performed. The CMP process is performed with respect to an entire upper surface of the semiconductor substrate 100. The lower metal interconnection 130b and the second barrier layer 125b, exposed through the CMP process are removed.

Preferably, a slurry having a higher etching selectivity to the lower metal interconnection 130b than the second barrier layer 125b is used in the CMP process. In other words, the polish rate of the lower metal interconnection 130b is greater than the polish rate of the second barrier layer 125b, typically by a factor of 2×, 3×, 5× or more.

After performing the CMP process, the height of the top surface of the lower metal interconnection 130b is coplanar with or lower than the top surface of the additional PMD layer 110. Alternatively, the height of the top surface of the lower metal interconnection 130b may be lower than that of the top surface of the lower PMD layer 110 by following the CMP process with wet etching the lower metal interconnection 130b (optionally using a predetermined mask pattern, if the wet etch does not selectively etch the lower metal interconnection 130b relative to the additional PMD layer 112).

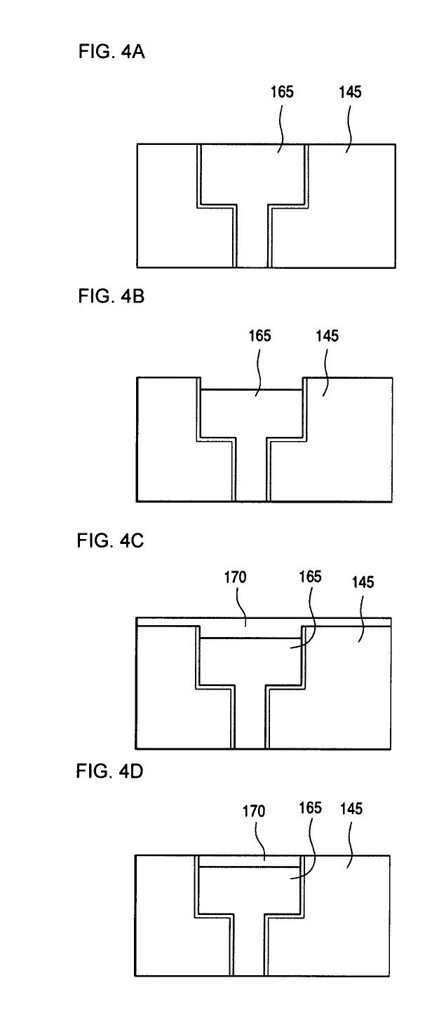

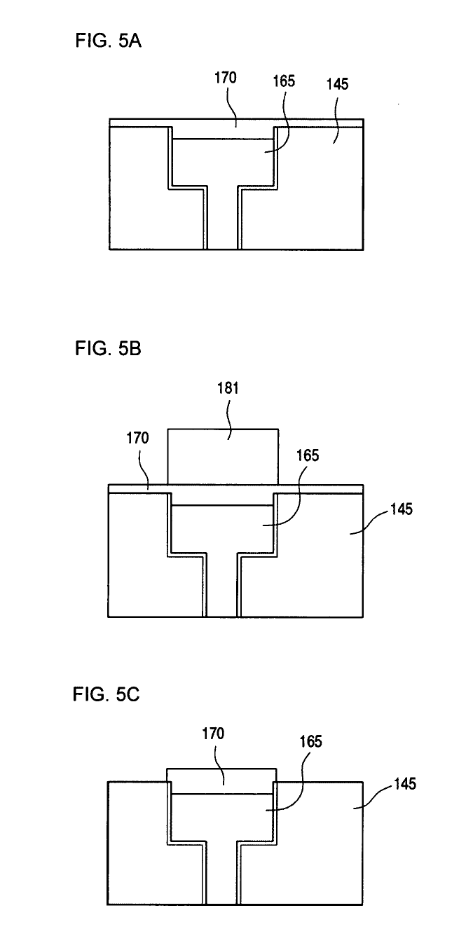

A lower capping barrier metal layer 140 having the same height as the additional PMD layer 110 is formed on the lower metal interconnection 130b, generally by a process as described below with regard to FIGS. 4A-4D or 5A-5C. The lower capping barrier metal layer 140 may include a conductive metal such as Ti, TiSiN, TiN, Ta, TaN, WSiN, WN, MoN, HfN, TiW alloy or Ru.

As described above, the lower capping barrier metal layer 140 is generally formed only on the lower metal interconnection 130b, so that it is possible to prevent the effective dielectric constant (effective k) from being increased by a barrier layer existing on the entire surface of the PMD layer (or an IMD layer, when the metal layer is formed on an underlying metal layer, rather than on an underlying silicon [pre-metal] layer) in the conventional technique. Accordingly, the reliability of the semiconductor device can be improved.

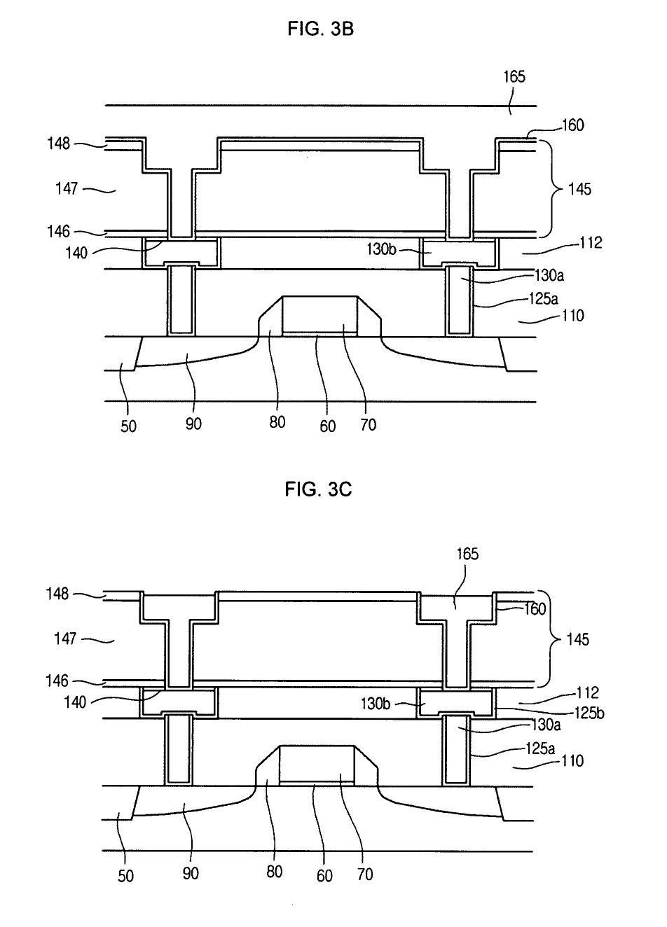

FIGS. 3a to 3c are cross-sectional views illustrating a method for forming an upper metal interconnection according to embodiments of the invention.

As illustrated in FIG. 3a, an IMD layer 145 is stacked on the additional PMD layer 112 and the lower capping barrier metal layer 140, and a photoresist pattern (not shown) is formed on the IMD layer 145. The IMD layer 145 is etched using the photoresist pattern as a mask, thereby forming an upper via hole 150 exposing the lower capping barrier metal layer 140. A recess (or etch) process of removing an upper portion of the IMD layer 145 in a predetermined thickness (or to a predetermined depth) using another photoresist pattern as a mask is performed on the IMD layer 145, thereby forming an upper trench 155.

As illustrated in FIG. 3a, the IMD layer 145 may comprise a plurality of insulating layers (as may each of the PMD layers 110 and 112). For example, the IMD layer 145 may comprise a lower dielectric barrier layer 146, a bulk dielectric layer 147, and an upper dielectric barrier/planarization layer 148. In wafer fabrication processes or technologies having a minimum critical dimension of 0.13 μm or larger, the lower dielectric barrier layer 146 may comprise an undoped silicate glass (USG), the bulk dielectric layer 147 may comprise a fluorine doped silicate glass (FSG), and the upper dielectric barrier/planarization layer 148 may comprise a plasma silane-based glass, a TEOS-based glass and/or an undoped silicate glass (USG) (e.g., a TEOS-on-USG stack). However, in wafer fabrication processes having a minimum critical dimension of 0.11 μm or smaller, the layer 146 may be absent, and the bulk dielectric layer 147 may comprise a low k dielectric such as SiOC and/or SiOCH.

As illustrated in FIG. 3b, the lower capping barrier metal layer 140 exposed through the upper via hole 150 may be removed. Alternatively, the lower capping barrier metal layer 140 exposed through the upper via hole 150 may not be removed.

The lower capping barrier metal layer 140 prevents the lower metal interconnection 130b from being diffused into the IMD layer 145 due to heat produced during a process of manufacturing a semiconductor device. As a result, it is possible to prevent an RC delay in the device.

A third barrier layer 160 and an upper metal interconnection 165 are stacked on the upper IMD layer 145 having the upper via hole 150 and the upper trench 155. Preferably, the upper metal interconnection 165 includes copper, and the third barrier layer 160 comprises a barrier against diffusion of copper (e.g., Ta, TaN, Hf, HfN, Ru, or combinations thereof such as TaN on Ta, HfN on Hf, etc.), similar to second barrier layer 125b.

As illustrated in FIG. 3c, the third barrier layer 160 and the upper metal interconnection 165 on the IMD layer 145, are removed through a CMP process, thereby patterning the third barrier layer 160 and the upper metal interconnection 165. A slurry having higher etching selectivity to the upper metal interconnection 165 than the third barrier layer 160 can be used in the CMP process.

After performing the CMP process, the height of the top surface of the upper metal interconnection 165 may be coplanar with or lower than that of the top surface of the IMD layer 145. However, the height of the top surface of the upper metal interconnection 165 may be lower than that of the top surface of the IMD layer 145 if the CMP process is followed by wet etching the upper metal interconnection 165 (optionally using a predetermined mask pattern, as described above).

After that, an upper capping barrier metal layer 170 is formed on the upper metal interconnection 165 as illustrated in FIG. 1. The upper capping barrier metal layer 170 may include a conductive metal or metal compound such as Ti, TiN, Ta, TaN, WSiN, WN, MoN, HfN, TiW alloy or Ru.

As described above, the upper capping barrier metal layer 170 is formed generally only on the upper metal interconnection 165, so that it is possible to prevent the effective dielectric constant (effective k) from being increased by a barrier layer existing on the entire surface of an IMD layer in the conventional technique. Accordingly, the reliability of the semiconductor device can be improved.

FIGS. 4a to 4d are cross-sectional views illustrating a method for forming the upper capping barrier metal layer 170 described in FIG. 1. FIGS. 5a to 5c are cross-sectional views illustrating another method for forming the upper capping barrier metal layer 170 described in FIG. 1.

For reference, the method for forming the upper capping barrier metal layer 170, illustrated in FIGS. 4a to 4d or 5a to 5c, may be identically applied to the method for forming the lower capping barrier metal layer 140, illustrated in FIG. 2d.

As illustrated in FIGS. 4a and 4b, the height of the top surface of the upper metal interconnection 165 is lower than that of the top surface of the IMD layer 145 through a CMP process (and optional wet etch process). As described above, this is because slurry having higher etching selectivity to the upper metal interconnection 165 than the third barrier layer 160 (and/or the uppermost material 148 in IMD layer 145) is used in the CMP process.

As illustrated in FIG. 4c, an upper capping barrier metal layer 170 is formed on the entire surface of the semiconductor substrate. As illustrated in FIG. 4d, the IMD layer 145 is exposed through a CMP process. Thus, the upper capping barrier metal layer 170 illustrated in FIG. 1 is formed.

However, when forming the upper capping barrier metal layer 170 using the method of FIGS. 4a to 4d, the thickness of the upper capping barrier metal layer 170 may not be completely uniform due to the dishing phenomenon caused by a CMP process. This may cause an RC delay or the like. Therefore, another method is provided.

FIGS. 5a to 5c illustrate another method for forming the upper capping barrier metal layer 170.

FIG. 5a is a cross-sectional view corresponding to FIG. 4c, in which an upper capping barrier metal layer 170 is formed. In order to eliminate the dishing phenomenon caused by a CMP process, a photoresist pattern 181 is formed as illustrated in FIG. 5b. To ensure adequate coverage of the upper capping barrier metal layer 170 by the photoresist pattern 181, the photoresist pattern 181 may be slightly wider than the upper capping barrier metal layer 170 (e.g., by about 2 times a 3σ tolerance for photolithography alignment variations).

As illustrated in 5c, the upper capping barrier metal layer 170 that is not coated with the photoresist pattern 181 is entirely etched and removed using the photoresist pattern 181 as a mask. When the photoresist pattern 180 is used, the thickness of the upper capping barrier metal layer 170 can be uniformly maintained as illustrated in FIG. 5c.

Thus, it is not likely that an RC delay is increased in connection of a pad through a wire. Accordingly, the reliability of the semiconductor device can be entirely improved.

According to the present disclosure, a capping barrier metal layer is formed generally only on a lower metal interconnection in order to prevent the diffusion of the lower metal interconnection into an overlying IMD layer in a damascene process, to reduce or prevent an increase of an effective dielectric constant of the IMD layer that surrounds the metal interconnection, without adversely affecting the resistance of the metal interconnection. Accordingly, the reliability, speed and characteristics of the semiconductor device can be improved.

According to exemplary methods for forming an upper or lower capping barrier metal layer, a capping barrier metal layer can be stably formed on a copper metal interconnection. As a result, the reliability and speed of the semiconductor device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for forming an interconnection in a semiconductor device, the method comprising the steps of:
(a) forming a first barrier layer on an inner wall of a first via hole in a first dielectric layer on a semiconductor substrate, and forming a first metal interconnection on the first barrier layer;
(b) stacking an insulating layer on the semiconductor substrate;
(c) forming a first trench in the insulating layer;
(d) forming a second barrier layer on an inner wall of the first trench and a second metal interconnection on the second barrier layer;
(e) forming a lower capping barrier metal layer on the second metal interconnection;
(f) forming a second dielectric layer;
(g) forming a second via hole and a second trench in the second dielectric layer;
(h) forming a third barrier layer on inner walls of the second via hole and the second trench, and forming an upper metal interconnection on the third barrier; and
(i) forming an upper capping barrier metal layer on the trench of the second dielectric layer.

2. The method as claimed in claim 1, wherein the step (d) comprises the sub-steps of:
(a) stacking a second barrier layer on an entire surface of the semiconductor substrate;
(b) stacking the second metal interconnection; and
(c) polishing the second barrier layer and the second metal interconnection until the insulating layer is exposed.

3. The method as claimed in claim 2, wherein said polishing is performed using a slurry that includes a material having higher etching selectivity for the second metal interconnection than the second barrier layer.

4. The method as claimed in claim 1, wherein the step (e) comprises the sub-steps of:
(a) stacking the lower capping barrier metal layer on the semiconductor substrate; and
(b) polishing the lower capping barrier metal layer until the insulating layer is exposed.

5. The method as claimed in claim 1, wherein the step (h) comprises the sub-steps of:
(a) stacking the third barrier layer on the entire surface of the semiconductor substrate;
(b) stacking the upper metal interconnection; and
(c) polishing the third barrier layer and the upper metal interconnection until the second dielectric layer is exposed.

6. The method as claimed in claim 5, wherein said polishing is performed using a slurry that includes a material having higher etching selectivity for the upper metal interconnection than the third barrier layer.

7. The method as claimed in claim 1, wherein the step (i) comprises the sub-steps of:
(a) stacking an upper capping barrier metal layer on the entire surface of the semiconductor substrate; and
(b) polishing the upper capping barrier metal layer until the second dielectric layer is exposed.

8. The method as claimed in claim 1, wherein the first metal interconnection includes tungsten.

9. The method as claimed in claim 1, wherein the second metal interconnection includes copper.

10. A method for forming a metal interconnection in a semiconductor device, the method comprising the steps of:
(a) forming a via hole in an insulating layer on a semiconductor substrate;
(b) forming a trench on the via hole;
(c) stacking a barrier metal layer;
(d) stacking a metal interconnection;
(e) polishing the barrier metal layer and the metal interconnection until the insulating layer is exposed; and
(f) forming a capping barrier metal layer on the metal interconnection.

11. The method as claimed in claim 10, wherein the step of forming the capping barrier metal layer comprises the sub-steps of:
(a) stacking the capping barrier metal layer on the semiconductor substrate; and
(b) polishing the capping barrier metal layer until the insulating layer is exposed.

12. The method as claimed in claim 10, wherein the step of forming the capping barrier metal layer comprises the sub-steps of:
(a) stacking the capping barrier metal layer on the substrate;
(b) forming a photoresist pattern on the capping barrier metal layer;
(c) etching the exposed capping barrier metal layer using the photoresist pattern as a mask; and
(d) removing the photoresist pattern.

13. A semiconductor device comprising:
(a) a semiconductor substrate having an isolation layer, a high-density junction area, a gate insulating layer and a gate electrode;
(b) a first insulating layer on the semiconductor substrate;
(c) a first via hole in the first insulating layer, the via hole having a first barrier layer on an inner wall of the via hole and a first metal interconnection on the first barrier layer;
(d) a first trench on the via hole, the first trench having a second barrier layer on an inner wall of the first trench and a second metal interconnection on the second barrier layer;
(e) a lower capping barrier metal layer covering the second metal interconnection in the trench;
(f) a second insulating layer on the first insulating layer;
(g) a second via hole and a second trench in the second insulating layer;
(h) a third barrier layer on inner walls of the second via hole and the second trench;
(i) an upper metal interconnection on the third barrier layer; and
(j) an upper capping barrier metal layer formed the upper metal interconnection.

14. The semiconductor device as claimed in claim 13, wherein each of the first and second insulating layers includes a phosphorous silicate glass (PSG), a boron phosphorous silicate glass (BPSG), a fluorine doped silicate glass (FSG), or an undoped silicate glass (USG).

15. The semiconductor device as claimed in claim 13, wherein the first metal interconnection includes tungsten.

16. The semiconductor device as claimed in claim 13, wherein the second metal interconnection includes copper.

17. The semiconductor device as claimed in claim 13, wherein the lower capping barrier metal layer includes Ti, TiSiN, TiN, Ta, TaN, WSiN, WN, MoN, HfN, TiW alloy or Ru.

18. The semiconductor device as claimed in claim 13, wherein the upper capping barrier metal layer includes Ti, TiSiN, TiN, Ta, TaN, WSiN, WN, MoN, HfN, TiW alloy or Ru.
